(19) United States
(12) Patent Application Publication
(10) Pub. No.: US 2025/0323611 A1
(43) Pub. Date: Oct. 16, 2025

(54) DIFFERENTIAL SIGNAL AMPLIFICATION SYSTEM, MEASUREMENT APPLICATION DEVICE, AND METHOD

(71) Applicant: Rohde & Schwarz GmbH & Co. KG, München (DE)

(72) Inventor: Ols HIDRI, München (DE)

(21) Appl. No.: 18/634,312

(22) Filed: Apr. 12, 2024

(51) Int. Cl. H03F 3/45; H03F 1/56

(52) U.S. Cl. CPC H03F 3/45085; H03F 1/565; H03F 3/45475; H03F 2200/261

(57) ABSTRACT

The present disclosure provides a differential signal amplification system comprising a differential input transmission line arrangement comprising a positive input signal transmission line, and a negative input signal transmission line, a differential output transmission line arrangement comprising a positive output signal transmission line, and a negative output signal transmission line, at least one differential amplification stage coupled to the differential input transmission line arrangement, and the differential output transmission line arrangement. The present disclosure further provides a respective measurement application device, and a respective method.

### TECHNICAL FIELD

The disclosure relates to a differential signal amplification system. The present disclosure further provides a respective measurement application device, and a respective method.

### BACKGROUND

Although applicable to any type of signal processing application, the present disclosure will mainly be described in conjunction with oscilloscopes in measurement applications.

Modern oscilloscopes, like ultra-high bandwidth oscilloscopes, need a variable gain amplifier at their input, also called the “front end”, in order for the oscilloscope to achieve optimum performance at a given analog input signal level.

Achieving ultra-high bandwidths for different gain settings is an extremely difficult task. Furthermore, low noise and high linearity performance should also be provided across the gain setting range.

Accordingly, there is a need for providing an improved amplifier system for oscilloscopes.

### SUMMARY

The above stated problem is solved by the features of the independent claims. It is understood, that independent claims of a claim category may be formed in analogy to the dependent claims of another claim category.

Accordingly, it is provided:

A differential signal amplification system comprising a differential input transmission line arrangement comprising a positive input signal transmission line, and a negative input signal transmission line, and a differential output transmission line arrangement comprising a positive output signal transmission line, and a negative output signal transmission line, and at least one differential amplification stage coupled to the differential input transmission line arrangement, and the differential output transmission line arrangement, and wherein the at least one differential amplification stage comprises a signal transmission matrix configured to at least one of controllably transmit a positive input signal from a positive signal input of the signal transmission matrix at least in part to at least one of a negative signal output of the signal transmission matrix and a positive signal output of the signal transmission matrix, and controllably transmit a negative input signal from a negative signal input of the signal transmission matrix at least in part to at least one of the positive signal output, and the negative signal output.

Further, it is provided:

A measurement application device comprising a differential signal input comprising a positive signal input port, and a negative signal input port, and a measurement signal processing arrangement comprising a positive input port, and a negative input port. The measurement application device further comprises a first differential signal amplification system according to any one of the embodiments disclosed herein, the differential signal amplification system comprising a differential input transmission line arrangement comprising a positive input signal transmission line coupled to the positive signal input port, and a negative input signal transmission line coupled to the negative signal input port, a differential output transmission line arrangement comprising a positive output signal transmission line coupled to the positive input port, and a negative output signal transmission line coupled to the negative input port, at least one differential amplification stage coupled to the differential input transmission line arrangement, and the differential output transmission line arrangement, wherein the at least one differential amplification stage comprises a signal transmission matrix configured to at least one of controllably transmit a positive input signal from a positive signal input of the signal transmission matrix at least in part to at least one of a negative signal output of the signal transmission matrix and a positive signal output of the signal transmission matrix, and controllably transmit a negative input signal from a negative signal input of the signal transmission matrix at least in part to at least one of the positive signal output, and the negative signal output.

Further, it is provided:

A differential signal amplification method comprising receiving a positive input signal of a differential input signal on a positive input signal transmission line, receiving a negative input signal of the differential input signal on a negative input signal transmission line, controllably overlaying the positive input signal at least in part with the negative input signal for amplification of the overlayed positive input signal, and outputting the amplified positive input signal on a negative output signal transmission line, and controllably overlaying the negative input signal at least in part with the positive input signal for amplification of the overlayed negative input signal, and outputting the amplified negative input signal on a positive output signal transmission line.

The present disclosure is based on the finding that Ultra-wideband (UWB) systems require variable gain amplifiers, VGAs, with large bandwidths for high time resolution in measurement applications, high spatial resolution in radar applications, and high data rates in telecommunication.

Circuit components like variable gain amplifiers may be used in such measurement equipment, radar systems, and telecommunications systems. VGAs may e.g., be used in oscilloscope front-ends in order to achieve a required signal-to-noise level, SNR, and a required linearity performance for a given analog input signal. VGAs may also be used e.g., in transceiver front-ends to regulate the transmitted power and prevent saturation of the receiver.

Distributed amplifiers, DAs, have broad bandwidths from DC to hundreds of GHz and offer low input/output return losses and flat group delays.

FIG. 1 illustrates a possible configuration of a microwave distributed amplifier, consisting of a cascade of N identical transconductance stages, all having their inputs connected to an input transmission line (single ended or differential depending on the stage input type), and all having their outputs connected to an output transmission line (single ended or differential depending on the stage output type).

In single ended applications, either the positive input signal transmission line, or the negative input signal transmission line, and the respective output signal transmission line may be connected to ground potential, or to a predefined electrical potential. This may be applied to any one of the embodiments of the differential signal amplification system disclosed herein.

In such arrangements, an equivalent input synthetic transmission line, composed of transmission line segments periodically loaded by the input capacitance of the transconductance stages, also called differential amplification stages, will possess a characteristic impedance lower than that of each individual input transmission line segment. This lower characteristic impedance, often referred to as Zci, typically represents the desired target input impedance. Further, an equivalent output synthetic transmission line, composed of transmission line segments periodically loaded by the output capacitance of the transconductance stages, will possess a characteristic impedance lower than that of each individual output transmission line segment. This lower characteristic impedance, often referred to as Zco, typically represents the desired target output impedance.

The synthetic lines used in such a setup possess an exceptionally wide bandwidth because they effectively incorporate the capacitance of the stages into an equivalent transmission line. Consequently, the impact of input or output capacitance is primarily in the form of signal delay rather than signal attenuation. As depicted in FIG. 1, when the input signal enters the synthetic line, it traverses the line and drives the gain stages sequentially. Each gain stage amplifies its respective input signal and presents it at the output transmission line, where the signals finally combine. To ensure constructive summation at the output transmission line, it is crucial for the signal delay propagation on the output synthetic line to match that of the input synthetic line. By meeting this condition, the overall gain of the distributed amplifier, which is the sum of gains from all stages, remains nearly constant even at extremely high frequencies. Consequently, the distributed amplifier achieves ultra-high bandwidth amplification.

The arrangement shown in FIG. 1 comprises a fixed number of transconductance stages, and a fixed amplification or gain level.

The differential signal amplification system according to the present disclosure improves such distributed amplifiers to provide a variable gain distributed amplifier. The differential signal amplification system according to the present disclosure, consequently, provides a high-bandwidth amplification with configurable gain level, wherein the configured gain level is essentially constant over the full bandwidth.

To this end, the differential signal amplification system comprises a differential input transmission line arrangement, and a differential output transmission line arrangement. The differential input transmission line arrangement comprises a positive input signal transmission line, and a negative input signal transmission line. The differential output transmission line arrangement comprises a positive output signal transmission line, and a negative output signal transmission line. The transmission lines according to the present disclosure may comprise so called semi-artificial transmission lines. Such semi-artificial transmission lines may e.g., comprise a two-port electrical network that has the characteristic impedance, transmission time delay, phase shift, or other parameter(s) of an equivalent real transmission line.

The differential signal amplification system further comprises at least one differential amplification stage coupled to the differential input transmission line arrangement, and the differential output transmission line arrangement. In embodiments, the differential signal amplification system may comprise at least two or more differential amplification stages.

The differential amplification stage comprises a signal transmission matrix that handles the signal transmission from a positive signal input to a positive signal output, and a negative signal output of the signal transmission matrix, and that handles the signal transmission from a negative signal input to the positive signal output, and the negative signal output. The positive signal input is coupled to the positive input signal transmission line, and the negative signal input a negative input signal transmission line.

The signal transmission matrix may controllably transmit a positive input signal from the positive signal input at least in part to at least one of the negative signal output, and the positive signal output. The signal transmission matrix may further controllably transmit a negative input signal from the negative signal input at least in part to at least one of the positive signal output, and the negative signal output.

With the signal transmission matrix, it is possible to generate a constructive or a destructive overlay of the positive input signal, and the negative input signal, or parts of the positive input signal, and the negative input signal at each one of the negative signal output, and the positive signal output of the signal transmission matrix. The expression “constructive overlay” is to be understood as providing an amplified signal on the respective output, wherein no actual overlay of two signals is required. Instead, only the respective signal may be amplified, while the other signal may be set to zero. An overlay of the signal to be amplified, and the other signal that is set to zero, will result in the amplified signal being provided at the output.

Each one of the differential amplification stages may, therefore, be configured to either output an amplified signal on the positive output signal transmission line, and the negative output signal transmission line (with constructive overlay) that is amplified with a predefined maximum amplification level, or to output no signal on the positive output signal transmission line, and the negative output signal transmission line (with destructive overlay). A differential amplification stage that outputs no signal to the differential output transmission line arrangement may also be seen as a deactivated differential amplification stage. If in the present disclosure, a differential amplification stage is described as being inactive or deactivated, it is to be understood, that the respective differential amplification stage is operating in the destructive overlay mode.

In embodiments, as will be described in more detail below, the overlay (constructive or destructive) not necessarily is a binary or full overlay. Instead, the signal transmission matrix may be configured to perform a gradually configurable or linear overlay. This allows linearly setting or configuring the overlay performed by the signal transmission matrix, and, therefore, indirectly the gain provided by each one of the differential amplification stages. The explanations provided with regard to a binary or full overlay apply mutatis mutandis to a gradually configurable or linear overlay.

In both cases, the circuitry attached to the differential input transmission line arrangement, and the differential output transmission line arrangement, will stay the same for every one of the differential amplification stages, no matter if the respective differential amplification stage is amplifying the input signal with a predefined maximum amplification level, or providing no signal, or is amplifying the input signal with a gain or amplification level that is between zero and the predefined maximum amplification level.

By providing the same circuitry attached to the differential input transmission line arrangement, and the differential output transmission line arrangement in any operating state of the differential amplification stages, the impedances provided by the differential amplification stages on the differential input transmission line arrangement, and the differential output transmission line arrangement will stay essentially the same or be constant.

Consequently, deactivated differential amplification stages do not contribute to the overall amplification, and at the same time deactivating a single differential amplification stage does essentially not influence the impedances on the differential input transmission line arrangement, and the differential output transmission line arrangement.

The differential signal amplification system, consequently, allows to easily configure the overall gain factor provided for the differential signal on the differential output transmission line arrangement, while at the same time providing essentially constant impedances on the differential input transmission line arrangement, and the differential output transmission line arrangement.

A measurement application device according to the present disclosure may comprise any device that may be used in a measurement application to acquire an input signal or to generate an output signal, or to perform additional or supporting functions in a measurement application. A measurement application device may also comprise or be implemented as program application or program applications, also called measurement program application or measurement program applications, that may be executed on a computer device and that may communicate with other measurement application devices in order to perform a measurement task. A measurement application, also called measurement setup, may e.g., comprise at least one or multiple different measurement application devices for performing electric, magnetic, or electromagnetic measurements, especially on single devices under test. Such electric, magnetic, or electromagnetic measurements may e.g., be performed in a measurement laboratory or in a production facility in the respective production line. An exemplary measurement application or measurement setup may serve to qualify the single devices under test i.e., to determine the proper electrical operation of the respective devices under test.

Measurement application devices to this end may comprise at least one signal acquisition section for acquiring electric, magnetic, or electromagnetic signals to be measured from a device under test, or at least one signal generation section for generating electric, magnetic, or electromagnetic signals that may be provided to the device under test. Such a signal acquisition section may comprise, but is not limited to, a front-end for acquiring, filtering, and attenuating or amplifying electrical signals. The signal generation section may comprise, but is not limited to, respective signal generators, amplifiers, and filters. In embodiments, the signal acquisition is performed via the signal acquisition section in a wired or contact-based manner or fashion. To this end, a respective measurement probe may be coupled to the measurement application device via a respective cable. In embodiments, the signal generation and emission are performed via the signal generation section in a wired or contact-based manner or fashion. To this end, a respective signal output probe may be coupled to the measurement application device via a respective cable, or the signal may be output directly via the cable e.g., to a device under test.

Further, when acquiring signals, measurement application devices may comprise a signal processing section that may process the acquired signals. Processing may comprise converting the acquired signals from analog to digital signals, and any other type of digital signal processing, for example, converting signals from the time-domain into the frequency-domain.

The measurement application devices may also comprise a user interface to display the acquired signals to a user and allow a user to control the measurement application devices. Of course, a housing may be provided that comprises the elements of the measurement application device. It is understood, that further elements, like power supply circuitry, and communication interfaces may be provided.

A measurement application device may be a stand-alone device that may be operated without any further element in a measurement application to perform tests on a device under test. Of course, communication capabilities may also be provided for the measurement application device to interact with other measurement application devices.

A measurement application device may comprise, for example, a signal acquisition device e.g., an oscilloscope, especially a digital oscilloscope, a spectrum analyzer, or a vector network analyzer. Such a measurement application device may also comprise a signal generation device e.g., a signal generator, especially an arbitrary signal generator, also called arbitrary waveform generator, or a vector signal generator. Further possible measurement application devices comprise devices like calibration standards, or measurement probe tips.

Of course, at least some of the possible functions, like signal acquisition and signal generation, may be combined in a single measurement application device.

In embodiments, the measurement application device may comprise pure data acquisition devices that are capable of acquiring an input signal and of providing the acquired input signal as digital input signal to a respective data storage or application server. Such pure data acquisition devices not necessarily comprise a user interface or display. Instead, such pure data acquisition devices may be controlled remotely e.g., via a respective data interface, like a network interface or a USB interface. The same applies to pure signal generation devices that may generate an output signal without comprising any user interface or configuration input elements. Instead, such signal generation devices may be operated remotely via a data connection.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to independent claim 1 can be combined in all variations with each other and the disclosure of the description is not limited to the claim dependencies as specified in the claim set. Further, the features of the dependent claims referring to independent claim 1 may be combined with any of the features of the other independent claims or the dependent claims relating to any one of the other independent claims. In a respective method, respective method steps may perform the function of the respective apparatus elements, and in a respective apparatus, respective apparatus elements may perform the respective method steps.

In an embodiment, which can be combined with all other embodiments mentioned above or below, the differential amplification stage may further comprise at least one of a positive bias control circuitry arranged between the positive output signal transmission line, and the positive signal output of the signal transmission matrix, and a negative bias control circuitry arranged between the negative output signal transmission line, and the negative signal output of the signal transmission matrix.

The positive bias control circuitry, and the negative bias control circuitry both serve to provide a predefined impedance on the differential output transmission line arrangement.

In an embodiment, the positive bias control circuitry may comprise an inductance coupled to the positive signal output, and a load path of a transistor coupled between the inductance and the positive output signal transmission line. The negative bias control circuitry may comprise an inductance coupled to the negative signal output, and a load path of a transistor coupled between the inductance and the negative output signal transmission line. The inductances may in embodiments be omitted, and the transistors may be directly coupled to the respective signal outputs of the signal transmission matrix.

Each one of the transistors may be provided with a respective bias current on the control input e.g., the base of the respective transistor, to set an operating point for the respective transistor.

In an embodiment, the collector of the transistor may be coupled to the respective output signal transmission line, and the emitter of the transistor may be coupled to the respective inductance.

By adjusting the bias current on the control input of the transistor, and setting the operating point for the respective transistor, the input impedance of the collector of the respective transistor is adjusted. With a constant bias current, the input impedance provided by the respective differential amplification stage to the differential output transmission line arrangement is essentially constant.

In embodiments, a controller may be provided that adjusts the bias currents to the bases of the transistors, to compensate any variations of the input impedance of the collectors of the transistors.

As already explained above, the impedance of any circuitry of the differential amplification stages that is attached to the differential output transmission line arrangement is to be kept as constant as possible. This is easily achieved with the positive bias control circuitry, and the negative bias control circuitry.

In another embodiment, which can be combined with all other embodiments mentioned above or below, the differential amplification stage may further comprise at least one of a positive amplifier arranged between the positive input signal transmission line, and the positive signal input of the signal transmission matrix, and a negative amplifier arranged between the negative input signal transmission line, and the negative signal input of the signal transmission matrix.

The positive amplifier, and the negative amplifier perform the actual amplification of the signal present at the differential input transmission line arrangement.

In embodiments, the positive amplifier may comprise a transistor, wherein the load path of the transistor may be coupled between the positive signal input, and ground. An optional resistor may be provided between the transistor and ground. Further, an optional inductance may be provided between the transistor and the positive signal input. The negative amplifier may also comprise a transistor, wherein the load path of the transistor may be coupled between the negative signal input and ground. An optional resistor may be provided between the transistor and ground. Further, an optional inductance may be provided between the transistor and the negative signal input. Each one of the amplifiers may comprise essentially the same maximum amplification or gain.

The control input of the transistor of the positive amplifier e.g., the base, may be coupled to the positive input signal transmission line, and the control input of the transistor of the negative amplifier e.g., the base, may be coupled to the negative input signal transmission line.

The impedance provided by the positive amplifier, and the negative amplifier on the differential input transmission line arrangement is defined by the base impedance of the transistors used in the amplifiers, which is constant over a wide range of operating conditions.

Consequently, the impedance provided by the respective differential amplification stage to the differential input transmission line arrangement may be kept constant over any possible operating state of the respective differential amplification stage, as explained above.

In a further embodiment, which can be combined with all other embodiments mentioned above or below, the signal transmission matrix may comprise a plurality of transmission elements that are configured to at least one of controllably transmit at least a part of the signal received via the positive signal input to the negative signal output and the positive signal output, and controllably transmit at least part of the signal received via the negative signal input to the positive signal output and the negative signal output.

In embodiments, the signal transmission matrix may use the transmission elements to individually distribute signals at the signal inputs between both signal outputs. In this context, the expression of a signal being “received” is to be understood at a signal path being present at the respective element or entity. No direction of a signal e.g., a voltage polarity or current flow direction, need to be implied by the expression of a signal being “received”, or a signal being transmitted. The term “transmit” with regard to a signal may in an embodiment refer to mirroring signals on the inputs to the outputs in a configurable way to provide a constructive or destructive overlay or amplification of the signals, as explained above.

With the transmission elements, the signal present at the positive signal input may fully be provided to the positive signal output, or may in part be provided to the positive signal output, and the negative signal output, or may fully be provided to the negative signal output. The same applies to the signal present at the negative signal input, that may fully be provided to the positive signal output, or may in part be provided to the positive signal output, and the negative signal output, or may fully be provided to the negative signal output.

During operation of the differential signal amplification system, the transmission elements may be controlled synchronously such that if transmission elements at the positive signal input provide part of the signal to the positive signal output, the respective transmission elements at the negative signal input provide the same part of the signal present at the negative signal input to the negative signal output, and vice versa. This type of control ensures that differential signals on the input side are mirrored and amplified correctly to the output side.

In another embodiment, which can be combined with all other embodiments mentioned above or below, the signal transmission matrix may comprise a first positive transmission element, and a second positive transmission element, a first negative transmission element, and a second negative transmission element, wherein the first positive transmission element is coupled between the positive signal input, and the negative signal output, wherein the second positive transmission element is coupled between the positive signal input, and the positive signal output, wherein the first negative transmission element is coupled between the negative signal input, and the positive signal output, and wherein the second negative transmission element is coupled between the negative signal input, and the negative signal output.

Such an arrangement provides four possible signal paths. A first signal path from the positive signal input to the negative signal output, a second signal path from the positive signal input, to the positive signal output, a third signal path from the negative signal input to the positive signal output, and a fourth signal path from the negative signal input to the negative signal output.

In an embodiment, which can be combined with all other embodiments mentioned above or below, the first positive transmission element, the second positive transmission element, the first negative transmission element, and the second negative transmission element may be configured to controllably transmit a variable part of an input signal from the respective signal input to the respective signal output.

During operation of the differential signal amplification system, each one of the transmission elements may be controlled to distribute the incoming signals as described above, to distribute variable parts of the signals present at the signal inputs to the two signal outputs.

This allows easily providing the constructive or destructive overlay of the input signals at the signal outputs, as already described above, by simply controlling the transmission elements accordingly.

In a further embodiment, which can be combined with all other embodiments mentioned above or below, the first positive transmission element, the second positive transmission element, the first negative transmission element, and the second negative transmission element may each comprise an amplifier. Optionally, each one of the amplifiers may comprises a controllable gain, especially an individually controllable gain that may be essentially continuous. The gain may in embodiments be controlled linearly.

The amplifiers may comprise a gain that may be controllable between 0 and 1, or −1 and 1. Thereby, amplification values of −1 and 1 may refer to the respective amplifier being saturated, and an amplification of −1 may refer to an inverted polarity with regard to amplification of 1. Between amplification values of 0 and 1 or −1 and 1, the amplifiers may comprise an essentially linear amplification characteristic.

If, for example, a signal provided at the positive signal input is to be distributed to both signal outputs with the same level, the first positive transmission element, and the second positive transmission element may both be set to the same gain level. Between the positive signal input, and the two signal outputs, the first positive transmission element, and the second positive transmission element will then operate like a voltage divider, and the signal will evenly distribute between the two signal outputs.

Analogously, a signal provided at the negative signal input may be distributed to both signal outputs with the same level, if the first negative transmission element, and the second negative transmission element are both set to the same gain level. Between the negative signal input, and the two signal outputs, the first negative transmission element, and the second negative transmission element will then operate like a voltage divider, and the signal will evenly distribute between the two signal outputs.

If used with a differential signal that is provided on the differential input transmission line arrangement, providing half of each signal on the signal inputs to each one of the signal outputs will result in destructive overlay, and a “deactivation” of the respective differential amplification stage, since a zero-level signal will be provided to the respective amplifiers.

If different gain levels are set for the first positive transmission element, and the second positive transmission element, as well as for the first negative transmission element, and the second negative transmission element, an overall gain between 0 and 1 may be set for the respective differential amplification stage. In such a situation, usually, the gain of the first positive transmission element, will be set equal to the gain of the first negative transmission element, and the gain of the second positive transmission element will be set equal to the gain of the second negative transmission element, in order to cancel out the same amount of the output signal on the respective signal output.

In another embodiment, which can be combined with all other embodiments mentioned above or below, the first positive transmission element, the second positive transmission element, the first negative transmission element, and the second negative transmission element may each comprise a switch.

In embodiments, the single transmission elements may, instead of linear amplifiers, be provided as switches. Such switch-based or binary transmission elements may be open or closed i.e., have a gain of 1 or 0.

As explained above, all switches may be closed in order to cancel out a differential signal at the signal outputs of the signal transmission matrix of a respective differential amplification stage to “deactivate” the respective differential amplification stage. If the respective differential amplification stage is to be activated i.e., is to provide amplified signals on the outputs, the first positive transmission element, and the first negative transmission element may be closed, while the first negative transmission element, and the second negative transmission element may be opened.

With such an arrangement, only a simple binary control of the transmission elements is required. In contrast, the variable gain of the differential signal amplification system may only be adjusted in discrete steps i.e., the gain level added by a single differential amplification stage.

In an embodiment, which can be combined with all other embodiments mentioned above or below, the signal transmission matrix may further comprise a third positive transmission element, and a third negative transmission element, wherein the third positive transmission element may be coupled between the positive signal input, and the negative signal output, i.e., parallel to the first positive transmission element, and wherein the third negative transmission element may be coupled between the negative signal input, and the positive signal output, i.e., parallel to the first negative transmission element, and wherein the third positive transmission element, and the third negative transmission element may each comprise a switch.

With only a first positive transmission element, and a second positive transmission element, and a first negative transmission element, and a second negative transmission element, in the “deactivated” mode of a differential amplification stage, four switches will be closed in the signal transmission matrix, and will, therefore, be electronically active between the signal inputs and the signal outputs. In case that a differential amplification stage is active i.e., amplifying a differential input signal, only two switches will be closed, and will, therefore, be electronically active between the signal inputs and the signal outputs.

Consequently, in case that a binary control is used, as explained above, in an embodiment with only a first positive transmission element, and a second positive transmission element, and a first negative transmission element, and a second negative transmission element, different loads are presented to the positive bias control circuitry, and the negative bias control circuitry, as well as the positive amplifier, and the negative amplifier.

Such varying loads may change the impedance of the positive bias control circuitry, and the negative bias control circuitry, or of the positive amplifier, and the negative amplifier. In certain limits, such changes of the impedances may be acceptable.

If, however, the changes of the impedances in a respective application reach an unacceptable level, the third positive transmission element, and the third negative transmission element may be used to compensate the load provided by the signal transmission matrix.

In such embodiments, there will always be two closed switches present on each one of the inputs and the outputs, and the load presented by the signal transmission matrix will always be the same.

In such embodiments, in the “deactivated” mode of a differential amplification stage, four switches will be closed in the signal transmission matrix, and will, therefore, be electronically active between the signal inputs and the signal outputs. These switches will be the first positive transmission element, the second positive transmission element, the first negative transmission element, and the second negative transmission element.

In case that a differential amplification stage is active i.e., amplifying a differential input signal, also four switches will be closed, and will, therefore, be electronically active between the signal inputs and the signal outputs. These switches will be the first positive transmission element, the third positive transmission element, the first negative transmission element, and the third negative transmission element.

With the third positive transmission element, and the third negative transmission element it is, therefore, easily possible to provide the differential signal amplification system with a simple binary control, and at the same time keep the impedances on the differential input transmission line arrangement, and the differential output transmission line arrangement constant.

In embodiments, at least some, especially all switches of the differential signal amplification system may comprise at least one transistor or transistor-based switching element.

In a further embodiment, which can be combined with all other embodiments mentioned above or below, the differential signal amplification system may further comprise an amplification controller coupled to the at least one differential amplification stage, and configured to at least one of control the signal transmission matrix to output signals received on the positive signal input via the negative signal output, and signals received on the negative signal input via the positive signal output, control the signal transmission matrix to output signals received on the positive signal input via the positive signal output, and signals received on the negative signal input via the negative signal output, and control the signal transmission matrix to destructively combine signals received on the positive signal input, and the negative signal input on the positive signal output, and the negative signal output.

The controller may comprise a controllable current or voltage source for each one of the transmission elements in the differential amplification stages.

By controlling the transmission elements accordingly, the respective differential amplification stages may be operated in a first mode of operation, in which a differential input signal is amplified on the outputs, or in a second mode of operation, in which a differential input signal is cancelled out on the outputs, or in a third mode of operation, in which the differential input signal is amplified with a predetermined gain level on the output.

In a further embodiment, which can be combined with all other embodiments mentioned above or below, the measurement application device may further comprise a differential signal amplification system comprising a differential input transmission line arrangement comprising a positive input signal transmission line coupled to the positive signal input port, and a negative input signal transmission line coupled to the negative signal input port, a differential output transmission line arrangement comprising a positive output signal transmission line coupled to the positive input port, and a negative output signal transmission line coupled to the negative input port, at least one differential amplification stage coupled to the differential input transmission line arrangement, and the differential output transmission line arrangement, wherein the at least one differential amplification stage comprises a signal transmission matrix configured to at least one of, controllably transmit a positive input signal from a positive signal input of the signal transmission matrix at least in part to at least one of a negative signal output of the signal transmission matrix and a positive signal output of the signal transmission matrix, and controllably transmit a negative input signal from a negative signal input of the signal transmission matrix at least in part to at least one of the positive signal output, and the negative signal output. The differential output transmission line arrangement of the first differential signal amplification system may be coupled to the differential input transmission line arrangement of the second differential signal amplification system.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of a distributed amplifier arrangement;

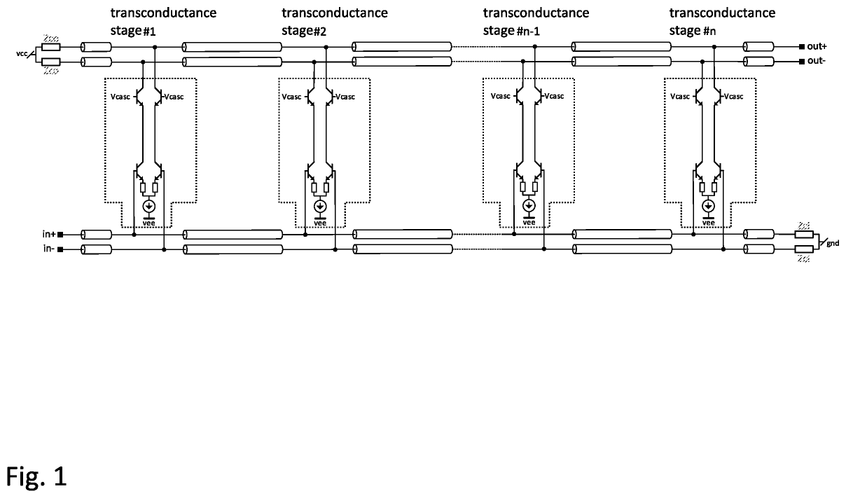

FIG. 2 shows a block diagram of an embodiment of a differential signal amplification system according to the present disclosure;

FIG. 3 shows a block diagram of another embodiment of a differential signal amplification system according to the present disclosure;

FIG. 4 shows a block diagram of a further embodiment of a differential signal amplification system according to the present disclosure;

FIG. 5 shows a diagram explaining the gain of a differential amplification stage of an embodiment of a differential signal amplification system according to the present disclosure;

FIG. 6 shows a block diagram of another embodiment of a differential signal amplification system according to the present disclosure;

FIG. 7 shows a block diagram of an embodiment of a measurement application device according to the present disclosure;

FIG. 8 shows a block diagram of an embodiment of another measurement application device according to the present disclosure; and

FIG. 9 shows a flow diagram of an embodiment of a method according to the present disclosure.

In the figures like reference signs denote like elements unless stated otherwise.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

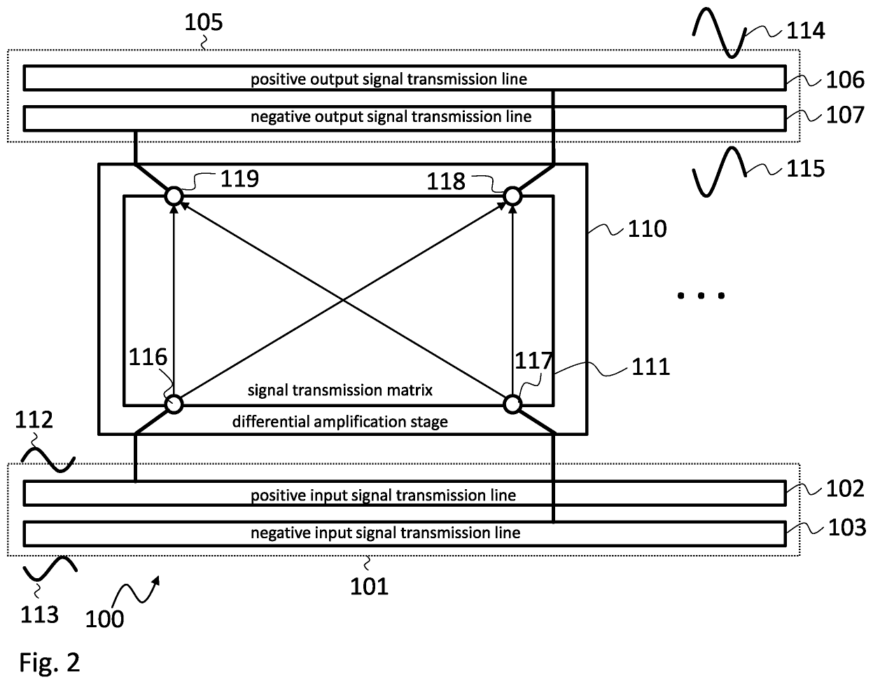

FIG. 2 shows a block diagram of a differential signal amplification system 100. The differential signal amplification system 100 comprises a differential input transmission line arrangement 101 that comprises a positive input signal transmission line 102, and a negative input signal transmission line 103. Further, the differential signal amplification system 100 comprises a differential output transmission line arrangement 105 that comprises a positive output signal transmission line 106, and a negative output signal transmission line 107. The differential signal amplification system 100 further comprises an exemplary differential amplification stage 110, wherein further differential amplification stages are hinted at by three dots. The differential amplification stage 110 is coupled to the differential input transmission line arrangement 101, and the differential output transmission line arrangement 105. The differential amplification stage 110 comprises a signal transmission matrix 111 that is coupled to the positive input signal transmission line 102 via a positive signal input 116, the negative input signal transmission line 103 via a negative signal input 117, the positive output signal transmission line 106 via a positive signal output 118, and the negative output signal transmission line 107 via a negative signal output 119. The explanations provided herein for any one of the embodiments of the differential signal amplification system apply mutatis mutandis to the differential signal amplification system 100.

During operation of the differential signal amplification system 100, the differential amplification stage 110 may controllably transmit a positive input signal 112 from the positive signal input 116 of the signal transmission matrix 111 at least in part to the negative signal output 119, and the positive signal output 118. The differential signal amplification system 100 may also transmit a negative input signal 113 from the negative signal input 117 at least in part to at least one of the positive signal output 118, and the negative signal output 119.

The expression “in part” in this regard refers to the differential amplification stage 110 operating like a controllable voltage divider or signal divider that may distribute the incoming signals to the two outputs 118, 119. If e.g., a differential signal is provided via the differential input transmission line arrangement 101, providing half of every input signal 112, 113 to each one of the outputs 118, 119, will lead to the signal parts cancelling each other out at the outputs 118, 119. If, in contrast, only the positive input signal 112 is provided to the negative signal output 119, and the negative input signal 113 is provided to the positive signal output 118, the signals will be fully available at the outputs 118, 119. Any factor between providing the full signal or no signal to any one of the outputs 118, 119 is also possible.

As explained above, more differential amplification stages are possible. With multiple differential amplification stages, the differential amplification stages may be identical, and each differential amplification stage may comprise the same maximum amplification or gain.

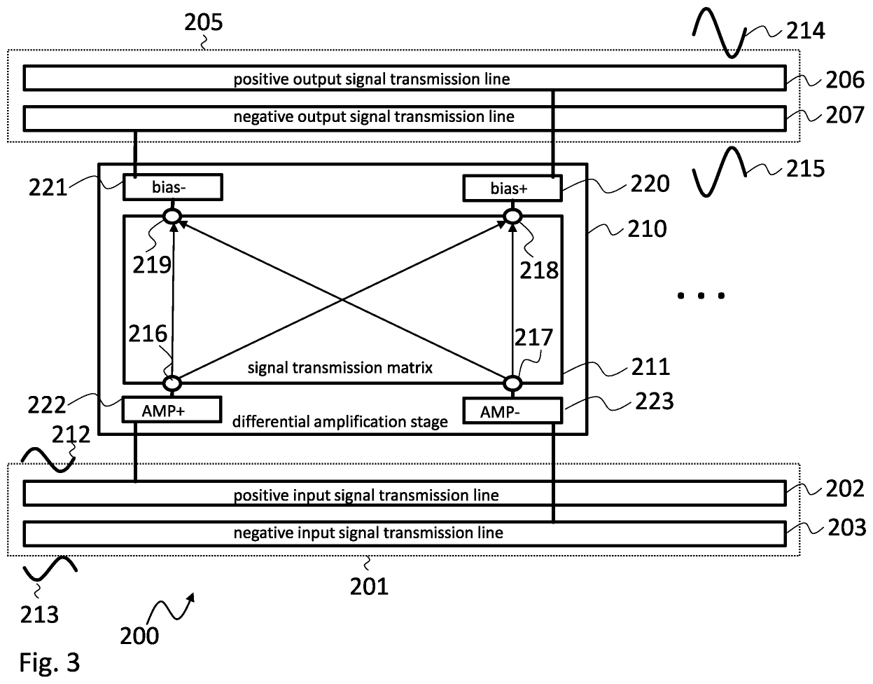

FIG. 3 shows a block diagram of a differential signal amplification system 200. The differential signal amplification system 200 is based on the differential signal amplification system 100. Therefore, the differential signal amplification system 200 comprises a differential input transmission line arrangement 201 that comprises a positive input signal transmission line 202, and a negative input signal transmission line 203. Further, the differential signal amplification system 200 comprises a differential output transmission line arrangement 205 that comprises a positive output signal transmission line 206, and a negative output signal transmission line 207. The differential signal amplification system 200 further comprises an exemplary differential amplification stage 210, wherein further differential amplification stages are hinted at by three dots. The differential amplification stage 210 is coupled to the differential input transmission line arrangement 201, and the differential output transmission line arrangement 205. The differential amplification stage 210 comprises a signal transmission matrix 211 that is coupled to the positive input signal transmission line 202 via a positive signal input 216, the negative input signal transmission line 203 via a negative signal input 217, the positive output signal transmission line 206 via a positive signal output 218, and the negative output signal transmission line 207 via a negative signal output 219. The explanations provided herein for any one of the embodiments of the differential signal amplification system apply mutatis mutandis to the differential signal amplification system 200.

In the differential signal amplification system 200, the differential amplification stage 210 further comprises a positive bias control circuitry 220 that is arranged between the positive signal output 218, and the positive output signal transmission line 206, a negative bias control circuitry 221 that is arranged between the negative signal output 219 and the negative output signal transmission line 207. Further, the differential amplification stage 210 comprises a positive amplifier 222 arranged between the positive input signal transmission line 202 and the positive signal input 216, and a negative amplifier 223 arranged between the negative input signal transmission line 203, and the negative signal input 217.

The positive bias control circuitry 220, and the negative bias control circuitry 221 serve for setting the impedance that is presented by the differential amplification stage 210 to the positive output signal transmission line 206, and the negative output signal transmission line 207.

The positive amplifier 222, and the negative amplifier 223 serve to provide the actual signal amplification for the positive input signal 212, and the negative input signal 213.

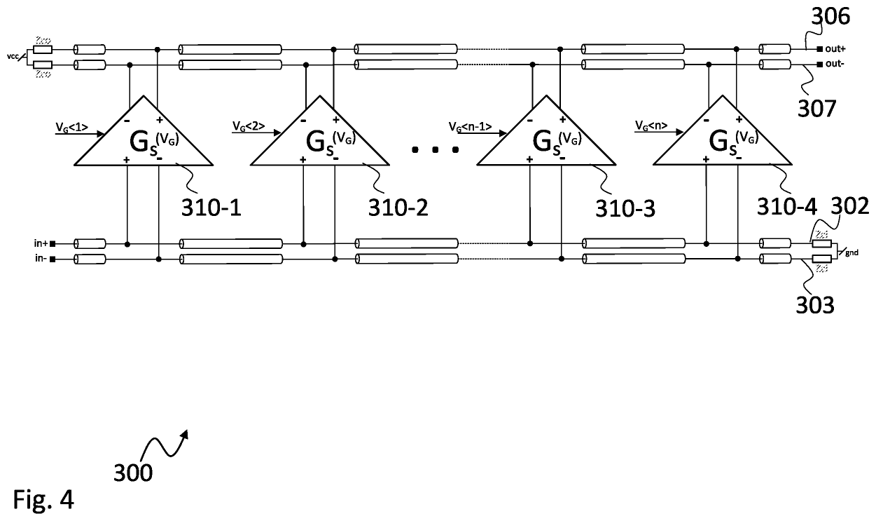

FIG. 4 shows a block diagram of a differential signal amplification system 300. The differential signal amplification system 300 is based on the differential signal amplification system 100. Therefore, the differential signal amplification system 300 comprises a differential input transmission line arrangement that comprises a positive input signal transmission line 302, and a negative input signal transmission line 303. Further, the differential signal amplification system 300 comprises a differential output transmission line arrangement that comprises a positive output signal transmission line 306, and a negative output signal transmission line 307. The differential signal amplification system 300 further comprises four exemplary differential amplification stages 310-1, 310-2, 310-3, 310-4, wherein further differential amplification stages are possible. The explanations provided herein for any one of the embodiments of the differential signal amplification system apply mutatis mutandis to the differential signal amplification system 300.

The end opposite to the signal inputs of the positive input signal transmission line 302, and the negative input signal transmission line 303 is in each case coupled to ground via a resistor, wherein a specific voltage instead of ground is possible. Further, the end opposite to the signal output of the positive output signal transmission line 306, and the negative output signal transmission line 307 is in each case coupled to a supply voltage source via a resistor, wherein ground instead of a specific supply voltage is possible.

The differential amplification stages 310-1, 310-2, 310-3, 310-4 each receive a control signal V_{G}<1>, V_{G}<2>, V_{G}<n−1>, V_{G}<n> that controls the signal transmission matrix in the respective differential amplification stage 310-1, 310-2, 310-3, 310-4.

As explained above, the total gain provided by the differential signal amplification system 300 is the mathematical sum of the single gains of the differential amplification stages 310-1, 310-2, 310-3, 310-4. The gain of the differential signal amplification system 300 is variable by separately controlling the gain of each one of the differential amplification stages 310-1, 310-2, 310-3, 310-4. In FIG. 3 it is shown a differential signal amplification system 300 where each stage has a variable gain and its gain is a function of its control signal V_{G}<1>, V_{G}<2>, V_{G}<n−1>, V_{G}<n>. The control signal V_{G}<1>, V_{G}<2>, V_{G}<n−1>, V_{G}<n> may be an analog control signal.

The output current of the stage i is given by:

Iₒᵤₜ=Gₛ(V_{G}<i>)*Vᵢₙ

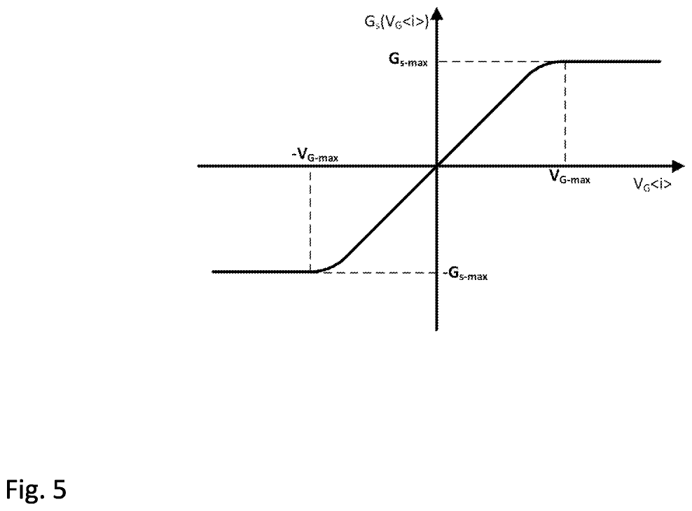

The gain Gₛ of each stage therefore depends on the value of the control signal V_{G}<i> with a possible characteristic as shown in FIG. 5.

As explained above, each one of the differential amplification stages 310-1, 310-2, 310-3, 310-4 may be provided with an individual control signal V_{G}<1>, V_{G}<2>, V_{G}<n−1>, V_{G}<n>, and provide an amplification between a negative maximum and a positive maximum (shown in FIG. 5). Consequently, the overall amplification of the differential signal amplification system 300 may be controlled linearly between a maximum negative total amplification or gain, and a maximum positive total amplification or gain.

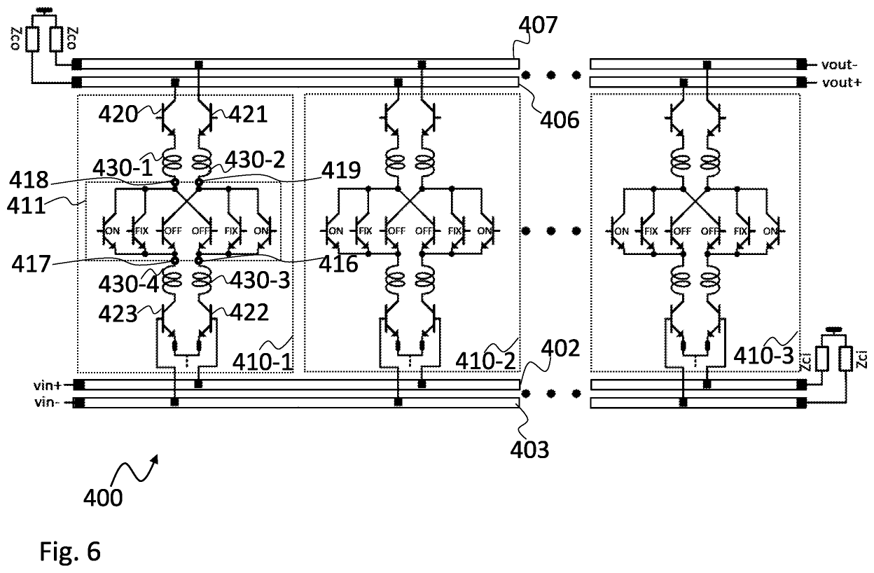

The above-described embodiment may e.g., be implemented with the specific embodiment as shown in FIG. 6, with only four transistors i.e., without the two optional transistors.

FIG. 5 shows a diagram explaining the gain of a differential amplification stage that may be used in an embodiment of a differential signal amplification system according to the present disclosure.

The diagram shows the control signal V_{G}<i> on the horizontal axis, and the amplification G (V_{G}<i>) on the vertical axis. It can be seen that the respective differential amplification stage comprises an essentially linear gain from a maximum negative gain −Gₛ₋ₘₐₓ that is achieved with a maximum negative control signal −V_{G-max}, to a maximum positive gain Gₛ₋ₘₐₓ that is achieved with a maximum positive control signal V_{G-max}.

Smaller values for V_{G}<i> than the maximum negative control signal −V_{G-max} and higher values for V_{G}<i> than the maximum positive control signal V_{G-max} would drive the respective differential amplification stage into saturation.

FIG. 6 shows a block diagram of a differential signal amplification system 400. The differential signal amplification system 400 is based on the differential signal amplification system 100. Therefore, the differential signal amplification system 400 comprises a differential input transmission line arrangement that comprises a positive input signal transmission line 402, and a negative input signal transmission line 403. Further, the differential signal amplification system 400 comprises a differential output transmission line arrangement that comprises a positive output signal transmission line 406, and a negative output signal transmission line 407. The differential signal amplification system 400 further comprises three exemplary differential amplification stages 410-1, 410-2, 410-3, wherein further differential amplification stages are hinted at by three dots. The explanations provided herein for any one of the embodiments of the differential signal amplification system apply mutatis mutandis to the differential signal amplification system 100.

The end opposite to the signal inputs of the positive input signal transmission line 402, and the negative input signal transmission line 403 is in each case coupled to ground via a resistor, wherein a specific voltage instead of ground is possible. Further, the end opposite to the signal output of the positive output signal transmission line 406, and the negative output signal transmission line 407 is in each case coupled to a supply voltage source via a resistor, wherein ground instead of a specific supply voltage is possible.

For sake of clarity, only the elements of the differential amplification stage 410-1 will be explained below. The explanations provided with regard to differential amplification stage 410-1 also apply to the other differential amplification stages.

The differential amplification stage 410-1 comprises a positive bias control circuitry 420 in the form of a transistor, wherein an inductor 430-1 is provided between the positive bias control circuitry 420, and the signal transmission matrix 411. Further, the differential amplification stage 410-1 comprises a negative bias control circuitry 421 in the form of a transistor, wherein an inductor 430-2 is provided between the negative bias control circuitry 421, and the signal transmission matrix 411.

The load paths of the positive bias control circuitry 420, and the negative bias control circuitry 421 are arranged between inductor 430-1 and inductor 430-2, and the positive output signal transmission line 406, and the negative output signal transmission line 407, respectively. The bases of the transistors that form the positive bias control circuitry 420, and the negative bias control circuitry 421 are provided with a respective bias control signal for setting an operating point of the resistors accordingly.

Further, the differential amplification stage 410-1 comprises a positive amplifier 422 in the form of a transistor, wherein an inductor 430-3 is provided between the positive amplifier 422, and the signal transmission matrix 411. In addition, the differential amplification stage 410-1 comprises a negative amplifier 423 in the form of a transistor, wherein an inductor 430-4 is provided between the negative amplifier 423, and the signal transmission matrix 411.

The load paths of the positive amplifier 422, and the negative amplifier 423 are arranged between inductor 430-3 and inductor 430-4, and ground or a reference voltage, respectively. The bases of the transistors forming the positive amplifier 422, and the negative amplifier 423 are connected to the positive input signal transmission line 402, and the negative input signal transmission line 403, respectively.

All transistors may be of the same type.

The signal transmission matrix 411 comprises six transistors (not referenced separately). A first and second one of the transistors couple the positive signal input 416 to the negative signal output 419, wherein one of the transistors is optional. A third transistor couples the positive signal input 416 to the positive signal output 418. A fourth and fifth of the transistors couple the negative signal input 417 to the positive signal output 418, wherein one of the transistors is optional. A sixth transistor couples the negative signal input 417 to the negative signal output 419.

The signal transmission matrix 411 may be used with a binary control. In such an embodiment, the transistors are used as switches. The signal is, therefore, evenly distributed or divided by the active transistors or the transistor-switches that are closed.

The signal transmission matrix 411 may alternatively also be used with a continuous control. In such an embodiment, the transistors are used as amplifiers with a variable gain, and an analog signal may be provided to the bases of the transistors.

In an exemplary embodiment all six transistors may be used with digital control. In such an embodiment, the first and second transistors denominated “on” and “fixed”, may be active or closed to fully transmit a signal from the positive signal input 416, to the negative signal output 419. At the same time, the fourth and fifth transistors may be closed to fully transmit a signal from the negative signal input 417 to the positive signal output 418. The third and sixth transistors may be deactivated i.e., the switches are open. In such a state, the respective differential amplification stage 410-1 is active and contributes to the overall amplification of the differential signal amplification system 400.

In a second state, one of the first and second transistor may be activated and the other one deactivated, and the third transistor may be activated i.e., the switch is closed. Further, one of the fourth and fifth transistor may be activated and the other one deactivated, and the sixth transistor may be activated. In this state, the active transistors operate like a voltage divider and half of the signal provided at the positive signal input 416 is transmitted to the positive signal output 418, and the negative signal output 419. At the same time, half of the signal provided at the negative signal input 417 is transmitted to the positive signal output 418, and the negative signal output 419. With a differential signal at the input, the signals will cancel each other out, and the respective differential amplification stage 410-1 is “deactivated”, while the impedances of the positive bias control circuitry 420, the negative bias control circuitry 421, the positive amplifier 422, and the negative amplifier 423 are still present on the respective signal transmission lines.

In an exemplary embodiment with only four transistors i.e. with the first or second transistor missing, and the fourth or fifth transistor missing, analog or non-binary control of the transistors may be implemented as explained above, in order to provide a continuous variable gain for the differential amplification stage 410-1.

It is understood, that the embodiments of the differential signal amplification system shown in the figures and explained herein serve to illustrate the operating principle of the differential signal amplification system. It is understood, that any further required elements, like additional circuit elements, power supply elements, and the like, may be provided in addition the elements disclosed herein.

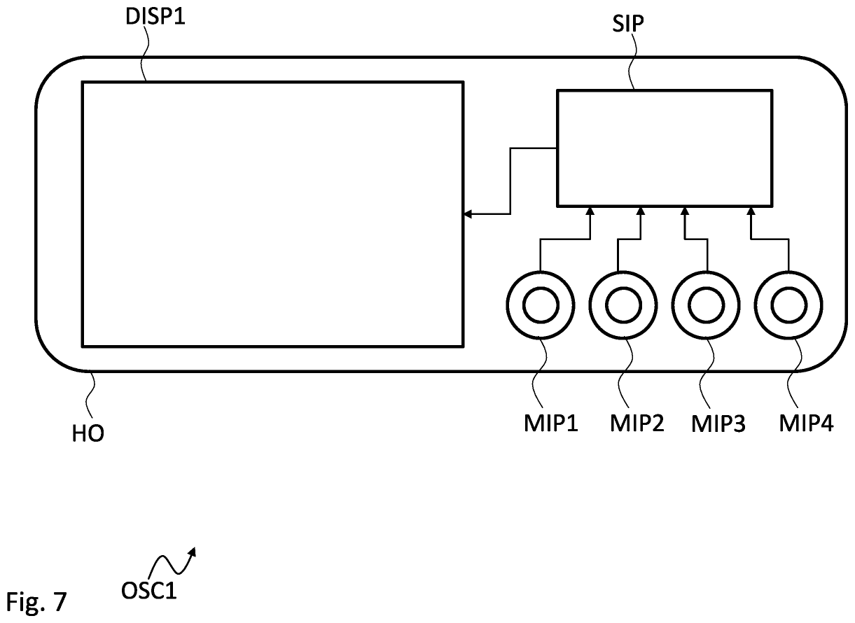

FIG. 7 shows a block diagram of an oscilloscope OSC1 that may be used with an embodiment of a differential signal amplification system according to the present disclosure.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

Although not explicitly shown, it is understood, that the oscilloscope OSC1 may also comprise signal outputs. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSC1 the measurement inputs MIP1, MIP2, MIP3, MIP4 may each comprise a differential signal amplification system according to any one of the embodiments disclosed herein.

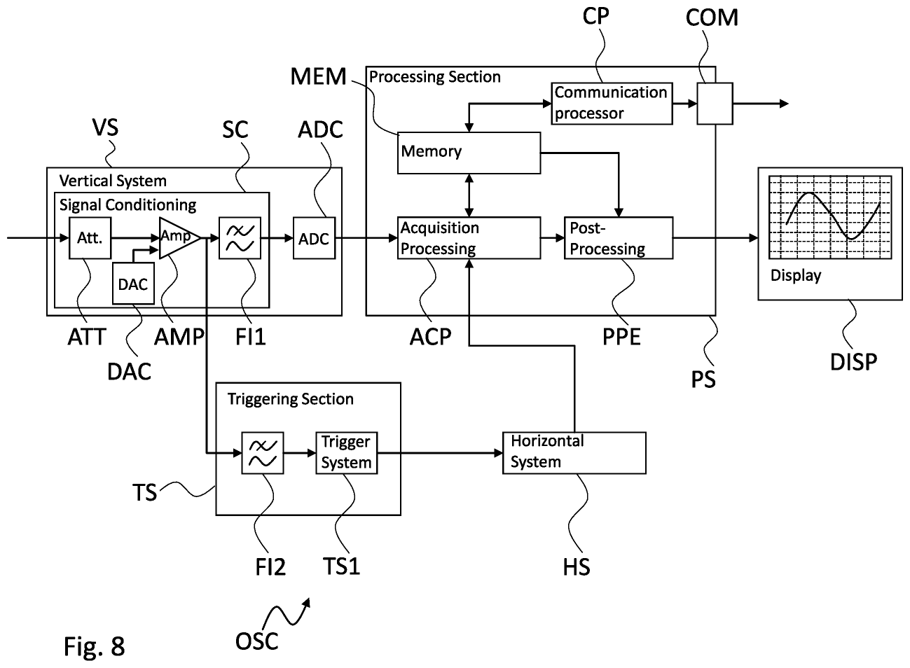

FIG. 8 shows a block diagram of an oscilloscope OSC that may be an implementation of a measurement application device according to the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS and the display DISP. It is understood, that the partitioning into five general sections is a logical partitioning and does not limit the placement and implementation of any of the elements of the oscilloscope OSC in any way.

The vertical system VS mainly serves for offsetting, attenuating and amplifying a signal to be acquired. The signal may for example be modified to fit in the available space on the display DISP or to comprise a vertical size as configured by a user.

To this end, the vertical system VS comprises a signal conditioning section SC with an attenuator ATT and a digital-to-analog-converter DAC that are coupled to an amplifier AMP. The amplifier AMP is coupled to a filter FI1, which in the shown example is provided as a low pass filter. The vertical system VS also comprises an analog-to-digital converter ADC that receives the output from the filter FI1 and converts the received analog signal into a digital signal.

The attenuator ATT and the amplifier AMP serve to scale the amplitude of the signal to be acquired to match the operation range of the analog-to-digital converter ADC. The digital-to-analog-converter DAC serves to modify the DC component of the input signal to be acquired to match the operation range of the analog-to-digital converter ADC. The filter FI1 serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC and the output of the horizontal system HS as well as to a memory MEM and a post processing element PPE.

The acquisition processing element ACP manages the acquisition of digital data from the analog-to-digital converter ADC and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

In the oscilloscope OSC, e.g., the vertical system VS may comprise any one of the embodiments of the differential signal amplification system disclosed herein for every signal input or signal to be acquired.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

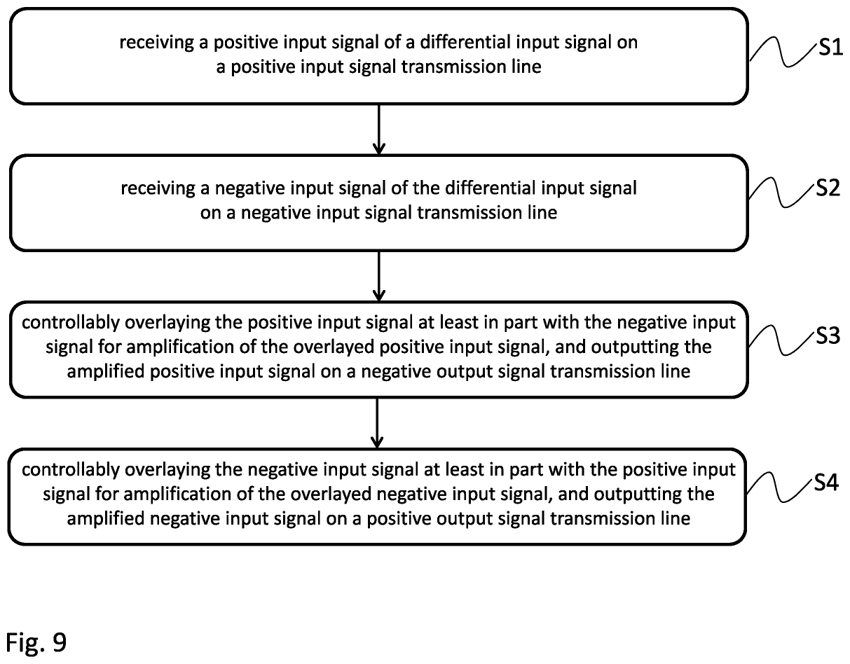

FIG. 9 shows a flow diagram of a differential signal amplification method.

The differential signal amplification method comprises receiving S1 a positive input signal of a differential input signal on a positive input signal transmission line, receiving S2 a negative input signal of the differential input signal on a negative input signal transmission line, controllably overlaying S3 the positive input signal at least in part with the negative input signal for amplification of the overlayed positive input signal, and outputting the amplified positive input signal on a negative output signal transmission line, and controllably overlaying S4 the negative input signal at least in part with the positive input signal for amplification of the overlayed negative input signal, and outputting the amplified negative input signal on a positive output signal transmission line.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100, 200, 300, 400 differential signal amplification system
101,201 differential input transmission line arrangement
102, 202, 302, 402 positive input signal transmission line
103, 203, 303, 403 negative input signal transmission line
105, 205 differential output transmission line arrangement
106, 206, 306, 406 positive output signal transmission line
107, 207, 307, 407 negative output signal transmission line
110, 210, 310-1, 310-2, 310-3, 310-4 differential amplification stage
410-1, 410-2, 410-3 differential amplification stage
111, 211, 411 signal transmission matrix
112, 212 positive input signal
113, 213 negative input signal
114, 214 positive output signal
115, 215 negative output signal
116, 216, 416 positive signal input
117, 217, 417 negative signal input
118, 218, 418 positive signal output
119, 219, 419 negative signal output
220, 420 positive bias control circuitry
221, 421 negative bias control circuitry
222, 422 positive amplifier
223, 423 negative amplifier
430-1, 430-2, 430-3, 430-4 inductor
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
DAC1 analog-to-digital converter
AMP amplifier
FI1 filter
DAC digital-to-analog converter
ADC analog-to-digital converter
TS triggering section
AMP2 amplifier
FI2 filter
TS1 trigger system
HS horizontal system
PS processing section
ACP acquisition processing element
MEM memory
PPE post processing element
DISP display
S1, S2, S3, S4 method steps

What is claimed is:

1. Differential signal amplification system comprising:
a differential input transmission line arrangement comprising a positive input signal transmission line, and a negative input signal transmission line;
a differential output transmission line arrangement comprising a positive output signal transmission line, and a negative output signal transmission line;
at least one differential amplification stage coupled to the differential input transmission line arrangement, and the differential output transmission line arrangement;
wherein the at least one differential amplification stage comprises a signal transmission matrix configured to at least one of:
controllably transmit a positive input signal from a positive signal input of the signal transmission matrix at least in part to at least one of a negative signal output of the signal transmission matrix and a positive signal output of the signal transmission matrix; and
controllably transmit a negative input signal from a negative signal input of the signal transmission matrix at least in part to at least one of the positive signal output, and the negative signal output.

2. Differential signal amplification system according to claim 1, wherein the differential amplification stage further comprises at least one of:
a positive bias control circuitry arranged between the positive output signal transmission line, and the positive signal output of the signal transmission matrix; and
a negative bias control circuitry arranged between the negative output signal transmission line, and the negative signal output of the signal transmission matrix.

3. Differential signal amplification system according to claim 1, wherein the differential amplification stage further comprises at least one of:
a positive amplifier arranged between the positive input signal transmission line, and the positive signal input of the signal transmission matrix; and
a negative amplifier arranged between the negative input signal transmission line, and the negative signal input of the signal transmission matrix.

4. Differential signal amplification system according to claim 1, wherein the signal transmission matrix comprises a plurality of transmission elements that are configured to at least one of:
controllably transmit at least a part of the signal received via the positive signal input to the negative signal output and the positive signal output; and
controllably transmit at least part of the signal received via the negative signal input to the positive signal output and the negative signal output.

5. Differential signal amplification system according to claim 1, wherein the signal transmission matrix comprises a first positive transmission element, and a second positive transmission element, a first negative transmission element, and a second negative transmission element;
wherein the first positive transmission element is coupled between the positive signal input, and the negative signal output;
wherein the second positive transmission element is coupled between the positive signal input, and the positive signal output;
wherein the first negative transmission element is coupled between the negative signal input, and the positive signal output; and
wherein the second negative transmission element is coupled between the negative signal input, and the negative signal output.

6. Differential signal amplification system according to claim 5, wherein the first positive transmission element, the second positive transmission element, the first negative transmission element, and the second negative transmission element are configured to controllably transmit a variable part of an input signal from the respective signal input to the respective signal output.

7. Differential signal amplification system according to claim 5, wherein the first positive transmission element, the second positive transmission element, the first negative transmission element, and the second negative transmission element each comprise an amplifier; and
wherein each one of the amplifiers comprises a controllable gain.

8. Differential signal amplification system according to claim 5, wherein the first positive transmission element, the second positive transmission element, the first negative transmission element, and the second negative transmission element each comprise a switch.

9. Differential signal amplification system according to claim 8, wherein the signal transmission matrix further comprises a third positive transmission element, and a third negative transmission element;
wherein the third positive transmission element is coupled between the positive signal input, and the negative signal output;
wherein the third negative transmission element is coupled between the negative signal input, and the positive signal output; and
wherein the third positive transmission element, and the third negative transmission element each comprise a switch.

10. Differential signal amplification system according to claim 1, further comprising an amplification controller coupled to the at least one differential amplification stage, and configured to at least one of:
control the signal transmission matrix to output signals received on the positive signal input via the negative signal output, and signals received on the negative signal input via the positive signal output;
control the signal transmission matrix to output signals received on the positive signal input via the positive signal output, and signals received on the negative signal input via the negative signal output; and
control the signal transmission matrix to destructively combine signals received on the positive signal input, and the negative signal input on the positive signal output, and the negative signal output.

11. Measurement application device comprising:
a differential signal input comprising a positive signal input port, and a negative signal input port;
a measurement signal processing arrangement comprising a positive input port, and a negative input port;
a first differential signal amplification system comprising:
a differential input transmission line arrangement comprising a positive input signal transmission line coupled to the positive signal input port, and a negative input signal transmission line coupled to the negative signal input port;
a differential output transmission line arrangement comprising a positive output signal transmission line coupled to the positive input port, and a negative output signal transmission line coupled to the negative input port;
at least one differential amplification stage coupled to the differential input transmission line arrangement, and the differential output transmission line arrangement;
wherein the at least one differential amplification stage comprises a signal transmission matrix configured to at least one of:
controllably transmit a positive input signal from a positive signal input of the signal transmission matrix at least in part to at least one of a negative signal output of the signal transmission matrix and a positive signal output of the signal transmission matrix; and
controllably transmit a negative input signal from a negative signal input of the signal transmission matrix at least in part to at least one of the positive signal output, and the negative signal output.

12. Measurement application device comprising a differential signal amplification system comprising:
a differential input transmission line arrangement comprising a positive input signal transmission line coupled to a positive signal input port, and a negative input signal transmission line coupled to a negative signal input port;
a differential output transmission line arrangement comprising a positive output signal transmission line coupled to the positive signal input port, and a negative output signal transmission line coupled to the negative signal input port;
at least one differential amplification stage coupled to the differential input transmission line arrangement, and the differential output transmission line arrangement;
wherein the at least one differential amplification stage comprises a signal transmission matrix configured to at least one of:
controllably transmit a positive input signal from a positive signal input of the signal transmission matrix at least in part to at least one of a negative signal output of the signal transmission matrix and a positive signal output of the signal transmission matrix; and
controllably transmit a negative input signal from a negative signal input of the signal transmission matrix at least in part to at least one of the positive signal output, and the negative signal output;
wherein the differential output transmission line arrangement of the first differential signal amplification system is coupled to the differential input transmission line arrangement of the second differential signal amplification system.

13. Differential signal amplification method comprising:
receiving a positive input signal of a differential input signal on a positive input signal transmission line;
receiving a negative input signal of the differential input signal on a negative input signal transmission line;
controllably overlaying the positive input signal at least in part with the negative input signal for amplification of the overlayed positive input signal, and outputting the amplified positive input signal on a negative output signal transmission line; and
controllably overlaying the negative input signal at least in part with the positive input signal for amplification of the overlayed negative input signal, and outputting the amplified negative input signal on a positive output signal transmission line.

14. Method according to claim 13, further comprising:
providing a predefined impedance on the positive output signal transmission line with a positive bias control circuitry; and
providing a predefined impedance on the negative output signal transmission line with a negative bias control circuitry.

15. Method according to claim 13, further comprising amplifying the overlayed positive input signal with the same gain as the overlayed negative input signal.

16. Method according to claim 13, wherein overlaying the positive input signal is performed with a signal transmission matrix comprising a plurality of transmission elements that are configured to at least one of:
controllably overlay at least a part of the positive input signal with the negative input signal; and
controllably overlay at least a part of the negative input signal with the positive input signal.

17. Method according to claim 16, wherein the signal transmission matrix comprises a first positive transmission element, and a second positive transmission element, a first negative transmission element, and a second negative transmission element;
wherein the first positive transmission element is coupled between a positive signal input of the signal transmission matrix, and a negative signal output of the signal transmission matrix;
wherein the second positive transmission element is coupled between the positive signal input, and a positive signal output;
wherein the first negative transmission element is coupled between a negative signal input of the signal transmission matrix, and a positive signal output;
wherein the second negative transmission element is coupled between the negative signal input, and the negative signal output;
wherein the positive input signal transmission line is coupled to the positive signal input; and
wherein the negative input signal transmission line is coupled to the negative signal input.

18. Method according to claim 17, wherein the first positive transmission element, the second positive transmission element, the first negative transmission element, and the second negative transmission element each controllably transmit a variable part of an input signal from the respective signal input to the respective signal output.

19. Method according to claim 17, wherein the first positive transmission element, the second positive transmission element, the first negative transmission element, and the second negative transmission element each comprise an amplifier; and
wherein each one of the amplifiers comprises a controllable gain.

20. Method according to claim 17, wherein the first positive transmission element, the second positive transmission element, the first negative transmission element, and the second negative transmission element each comprise a switch.

21. Method according to claim 20, wherein the signal transmission matrix further comprises a third positive transmission element, and a third negative transmission element;
wherein the third positive transmission element is coupled between the positive signal input, and the negative signal output;
wherein the third negative transmission element is coupled between the negative signal input, and the positive signal output; and
wherein the third positive transmission element, and the third negative transmission element each comprise a switch.
